(19) United States
(12) Patent Application Publication
(10) Pub. No.: US 2026/0093917 A1
(43) Pub. Date: Apr. 2, 2026

(54) INFORMATION PROCESSING SYSTEM AND NON-TRANSITORY COMPUTER-READABLE MEDIUM

(71) Applicant: TOYOTA JIDOSHA KABUSHIKI KAISHA, Aichi-ken (JP)

(72) Inventors: Nicolas BOUGIE, Chiyoda-ku (JP); Narimasa WATANABE, Chofu-shi (JP)

(21) Appl. No.: 19/338,422

(22) Filed: Sep. 24, 2025

(30) Foreign Application Priority Data
Sep. 27, 2024 (JP) 2024-168981

(51) Int. Cl. G06F 40/279; G06F 30/20

(52) U.S. Cl. CPC G06F 40/279; G06F 30/20

(57) ABSTRACT

An information processing system comprises a processor system and a memory system. The memory system stores instructions which, when executed by the processor system, cause the information processing system to instantiate an agent. The agent includes an agent memory for storing historical data associated with the agent; a first large language model conditioned on persona data characterizing a persona of the agent; a second large language model; and a control module. The control module is configured to: cause the first large language model to generate one or more actions based on the historical data, cause the second large language model to output a rating for the one or more actions generated by the first large language model, and cause the first large language model to update the one or more actions based on the rating output by the second large language model.

### CROSS-REFERENCE TO RELATED APPLICATION

This application claims priority to Japanese Patent Application No. 2024-168981, filed on Sep. 27, 2024, the entire contents of which are incorporated herein by reference.

### TECHNICAL FIELD

The present disclosure relates to an information processing system and a non-transitory computer-readable medium. More particularly, the present disclosure relates to an information processing system and a non-transitory computer-readable medium for simulating human behavior.

### BACKGROUND

Techniques for predicting human behavior based on history information are known. For example, Patent Literature (PTL) 1 discloses a behavior prediction apparatus that predicts human behavior using a prediction model that is trained on the basis of behavior history information for a human.

### CITATION LIST

### Patent Literature

PTL 1: JP 7476984 B2

### SUMMARY

Simulation or prediction of human behavior may be utilized in various applications, such as urban planning, crowd simulation, recommendation systems, sales prediction, and personalized marketing campaigns. Thus, techniques which provide improved simulation of human behavior in terms of accuracy and/or computational efficiency are desirable.

An information processing system according to the present disclosure includes: a processor system; and a memory system; wherein the memory system stores instructions which, when executed by the processor system, cause the information processing system to instantiate an agent comprising: an agent memory for storing historical data associated with the agent; a first large language model conditioned on persona data characterizing a persona of the agent; a second large language model; and a control module configured to: cause the first large language model to generate one or more actions based on the historical data, cause the second large language model to output a rating for the one or more actions generated by the first large language model, and cause the first large language model to update the one or more actions based on the rating output by the second large language model.

A non-transitory computer-readable medium according to the present disclosure stores instructions which, when executed by an information processing system, cause the information processing system to instantiate an agent comprising: an agent memory for storing historical data associated with the agent; a first large language model conditioned on persona data characterizing a persona of the agent; a second large language model; and a control module configured to: cause the first large language model to generate one or more actions based on the historical data, cause the second large language model to output a rating for the one or more actions generated by the first large language model, and cause the first large language model to update the one or more actions based on the rating output by the second large language model.

The information processing system and the non-transitory computer-readable medium of the present disclosure provides simulation of human behavior with improved accuracy.

### BRIEF DESCRIPTION OF THE DRAWINGS

In the accompanying drawings:

FIG. 1 is a schematic diagram illustrating an example configuration of an information processing system;

FIG. 2 is a schematic diagram illustrating an example an agent; and

FIG. 3 is a flow diagram illustrating an example of a process for simulating human behavior.

### DETAILED DESCRIPTION

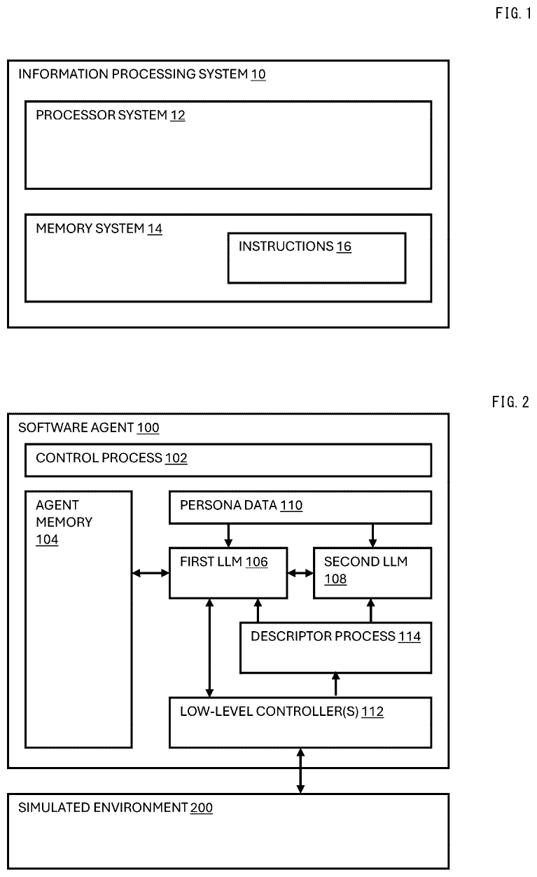

FIG. 1 is a schematic diagram illustrating an example configuration of an information processing system 10 according to an embodiment. The information processing system 10 includes a processor system 12 and a memory system 14. The processor system 12 includes one or more processors and the memory system 14 includes one or more memory units. The information processing system 10 illustrated in FIG. 1 has been simplified for ease of understanding, but it will be understood that it may include various other components, such as one or more network interfaces, one or more communication interfaces, one or more input interfaces, and/or the like.

The processing system 12 may include one or more processors, one or more dedicated circuits, or a combination thereof. The one or more processors may include a general-purpose processor, such as a central processing unit (CPU), a dedicated processor optimized for a particular purpose, such as graphics processing unit (GPU), or any combination thereof. Examples of a dedicated circuit are a field-programmable gate array (FPGA) and an application specific integrated circuit (ASIC). The processing system 12 executes information processing to control operations performed by the information processing system 10.

The memory system 14 includes, for example, one or more semiconductor memories, one or more magnetic memories, one or more optical memories, or any combination thereof. The memory system 14 may function as main memory, auxiliary memory, cache memory, or any combination thereof. Examples of suitable semiconductor memory include Random Access Memory (RAM) and Read Only Memory (ROM). Examples of RAM include Static RAM (SRAM) or Dynamic RAM (DRAM). Examples of ROM include Electrically Erasable Programmable ROM (EEPROM). The memory system 14 stores instructions and information for use in operations performed by the information processing apparatus 10.

The memory system 14 stores instructions 16 which, when executed by the processor system 12, implement one or more functions of the information processing system 10. The instructions 16 may be supplied to the information processing system 10 in a separate non-transitory computer-readable medium, such as an optical disk or a solid-state drive (SSD). Alternatively, the instructions 16 may be received over a network (not shown), such as the Internet, a mobile communication network, an ad-hoc network, a local area network (LAN), a metropolitan area network (MAN), or any combination thereof.

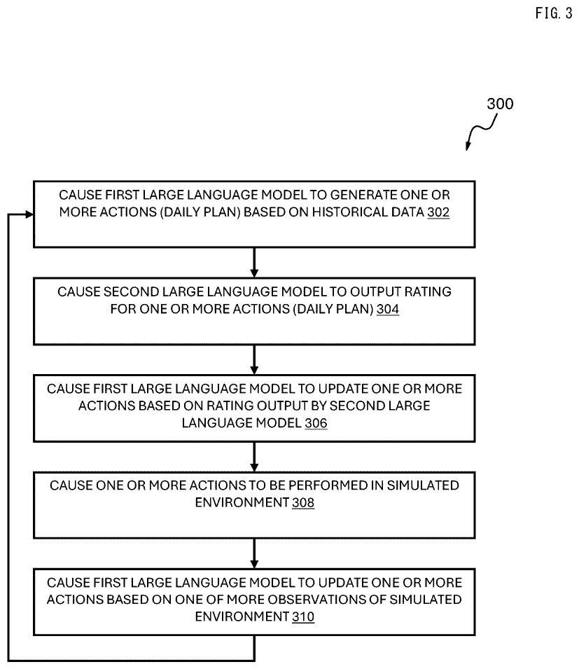

The information processing system 10 is configured to simulate or predict human behavior using artificial intelligence. More specifically, the information processing system 10 is configured to instantiate a software agent (hereinafter referred to simply as an “agent”) which simulates one or more human activities on the basis of persona data that characterizes a desired persona for the agent. In addition, the information processing system 10 may be configured to simulate or predict human behavior on the basis of an agent memory that stores historical data that characterizes one or more actions performed by the agent in the past. These aspects will be described in more detail below with reference to FIG. 2 and FIG. 3.

FIG. 2 is a schematic diagram illustrating an agent 100 instantiated by the information processing system 10 of FIG. 1. For ease of explanation, FIG. 2 illustrates the agent 100 in functional terms, with each block representing a discrete unit of functionality implemented in software by the agent 100. However, it will be appreciated that, at an implementation level, the functionality shown in FIG. 2 may be combined and/or divided without departing from the principles of the present disclosure discussed below in more detail.

The agent 100 includes a control module 102, an agent memory 104, a first large language model (LLM) 106, a second LLM 108, persona data 110, one or more low-level controllers 112 and a descriptor module 114.

The agent 100 is able to interact with a simulated environment 200. The simulated environment 200 may be implemented by the information processing system 10 or a separate system external to the information processing system 10. The simulated environment 200 is a virtual environment with which the agent 100 is able to interact to perform various actions or tasks. For example, the simulated environment 200 may be a simulation of a town or city, in which the agent 100 resides. In some embodiments, multiple agents may interact with the simulated environment 200, thereby enabling the multiple agents to interact with each other. Interaction with the simulated environment 200 may be realized via an Application Programming Interface (API) provided by the simulated environment 200.

The control module 102 is configured to provide overall control of the agent 100. Specifically, the control module 102 is configured to control or orchestrate operations performed by the first LLM 106, the second LLM 108, the one or more low-level controllers 112, and the descriptor module 114, to generate the one or more actions. The control module 102 may perform this control by instructing each of the first LLM 106, the second LLM 108, the one or more low-level controllers 112, and the descriptor module 114 according to a control procedure, whereby the controller instructs each component of the agent 100 to perform specific tasks. Such instructions be provided according to a specific syntax, an API, and/or may be provided in natural language form. For example, the control module 102 may control the first LLM 106 and the second LLM 108 by issuing one or more natural language prompts.

The persona data 110 specifies or characterizes a human to be simulated by the agent 100. That is, the persona data 110 encapsulates the human characteristics of the agent 100 and enables the agent 110 to simulate human behavior in a realistic manner. The persona data 110 may include one or more parameters characterizing the persona of the agent 100, and/or one or more natural language descriptions of the persona of the agent 100. For example, the persona data 110 may include one or more parameters characterizing personality, physical attributes, interests, and/or the background of the human to be simulated by the agent 100. Here, personality may be specified in terms of one or more parameters or scores corresponding to one or more personality attributes. Alternatively, or additionally, personality may be specified in terms of a natural language description.

The persona data 110 may be generated on the basis of historical data obtained from a human population. For example, such historical data may be obtained via a system that monitors the activities of the human population. In another example, the historical data may be obtained from historical data generated by the agent 100 itself. Based on this historical data, a summary of personality attributes is generated in natural language form. Using this summary, a LLM is used to generate a candidate persona that is consistent with the historical data. For example, the LLM may be instructed to generate a plurality of candidate personas and provide a score indicating consistency with the historical data for each of the candidate personas. In some cases, diversity in the candidate personas may be enhanced by providing the LLM with a set of possible characteristics to select from, such as a set of different occupations. Once a suitable persona has been selected, the selected persona is stored in the persona data 110.

The agent memory 104 stores historical data for the agent 100. The historical data provides a record of the past actions and experiences of the agent 100. The agent memory 104 may be filled in real-time as the agent 100 interacts with the simulated environment 200. Alternatively, or additionally, the agent memory 104 may be initialized on the basis of historical data generated by the agent 100 in a pervious simulation. The agent memory 104 serves as a long-term record of the actions, observations, feelings, and thoughts of the agent 100, and thus characterizes the internal state of the agent 100.

The first LLM 106 functions as a high-level planner LLM and is configured to generate a daily plan including one or more actions to be performed by the agent 100. Specifically, the first LLM 106 is conditioned on the persona data 110 to generate a daily plan that is consistent with the persona associated with the agent 100. The first LLM 106 may refer to the agent memory 104 to ensure that the daily plan is consistent with the history of the agent 100. Typically, the first LLM 106 may generate the daily plan on a daily basis (i.e., once a day). The daily plan may specify one or more actions to be performed according to one-hour time slots, together with locations where each action is to be performed, and any sub-tasks associated with each action.

The first LLM 106 outputs the daily plan to the second LLM 108. The second LLM 108 functions as a critic LLM and is configured to critique the daily plan generated by the first LLM 106. More specifically, the second LLM 108 is configured to determine whether the daily plan generated by the first LLM 106 is realistic and is consistent with the persona defined by the persona data 110 and/or the historical data stored in the agent memory 104. The second LLM 108 may also determine whether the daily plan is consistent with one or more external contexts, such as the simulated environment 200, cultural norms and/or human customs. The second LLM 108 outputs a rating for the daily plan to the first LLM 106. The rating may include a score for the daily plan, and/or feedback regarding the daily plan in natural language form.

Upon receipt of the feedback, the first LLM 106 may update or change the daily plan, as necessary. Thus, by refining the daily plan based on the feedback from the second LLM 108, the first LLM 106 is able to generate a realistic daily plan that is conditioned on the persona data 110 and is consistent with the internal state of the agent 100 characterized by historical data stored in the agent memory 104. In this manner, the agent 100 is able to generate realist human behavior.

The first LLM 106 and the second LLM 106 may be implemented using a pre-trained LLM, such the Generative Pre-trained Transformer 4 (GPT-4) and the like created by OpenAI of San Francisco, California. In other embodiments, the first LLM 106 and the second LLM 106 may be implemented by fine-tuning a pre-trained LLM or by training a LLM specifically for use as the first LLM 106 and/or the second LLM.

After the daily plan has been generated, critiqued and, if necessary, updated, it is executed in the simulated environment 200. Execution of the daily plan may be delegated to the one or more low-level controllers 112. The one or more low-level controllers 112 are configured to implement one or more low-level tasks necessary to enact the daily plan. For example, the one or more low-level controllers 112 may include a controller that is specialized in predicting the optimal way to travel between two locations in the simulated environment 200. The one or more low-level controllers 112 may include one or more LLMs trained to perform specific low-level tasks, and/or one or more models based on behavioral trees, reinforced learning (RL), neural networks, and/or the like. Typically, the one or more low-level controllers 112 do not account for the persona of the agent 100 and perform low-level tasks based on defined policies. Thus, by delegating the low-level tasks necessary to enact the daily plan to the one or more low-level controllers 112, the agent 100 is able to simulate human behavior with improved computational efficiency.

Execution of the daily plan in the simulated environment 200 may include several steps. First, the agent 100 may make one or more observations of the simulated environment 200. These observations may be made by the one or more low-level controllers 112 which control the interaction between the agent 100 and the simulated environment 200. In some embodiments, these observations may be visual observations that are translated into natural language by the descriptor module 114. In such embodiments, the descriptor module 114 may be realized by a vision language model (VLM) that is configured to caption the visual observations made by the one or more low-level controllers 112, and provide the caption to the first LLM 106 and/or the second LLM 108 in the form of natural language text.

Upon receipt of the observations from the low-level controllers 112 and/or the descriptor module 114, the first LLM 106 determines whether the one or more actions forming the daily plan need to be changed. For example, based on the observations, the first LLM 106 may estimate a current mood of the agent 100, a physical status of the agent 100 (e.g., hunger, fatigue) and determine whether the daily plan requires revision. For example, if the first LLM 106 determines that the agent 100 is hungry and daily plan does not involve eating for several hours, the first LLM 106 may decide to go to a restaurant in the simulated environment 200, and revise the daily plan accordingly. In a further example, the first LLM 106 may determine that the daily plan requires revision if the one or more observations indicate that it is raining at the current location of the agent 100 in the simulated environment 200, and the daily plan involves one or more outdoor activities.

The one or more observations of the simulated environment 200 may also be used to update the historical data stored in the agent memory 104 to ensure that the historical data accurately reflects the experiences of the agent 100 in the simulated environment 200. In this manner, the experiences of the agent 100 in the simulated environment 200 can be reflected in future generation of a daily plan by the first LLM 106, thereby enabling more accurate simulation of human behavior.

In some embodiments, the agent 100 may provide an interface (not shown), such as an API, which allows interrogation of the first LLM 106 via one or more natural language prompts. For example, a human operator may use the interface to ask agent 100 why it performed or is performing a certain action in the simulated environment 200. In this manner, the human operator is able to gain insight into the persona of the agent 100. Such insight may be valuable for urban planning in respect of the town or city being simulated by the simulated environment 200.

FIG. 3 is a flow diagram illustrating a method 300 for simulating one or more human activities according to an embodiment. For clarity, the following description assumes that the method 300 is performed by the control module 102. However, it will be understood that the method 300 may be performed by any component of the agent 100, or any combination of components of the agent 100. Here, the method 300 is an example of the control procedure explained above with reference to FIG. 2.

First, in step 302, the control module 102 causes the first LLM 106 to generate one or more actions based on the historical data stored in the agent memory 104. As discussed above, the one or more actions may constitute a daily plan. Here, the first LLM 106 is conditioned on the basis of the persona data 110, so the one or more actions reflect the persona and past experiences of the agent 100.

Next, in step 304, the control module 102 causes the second LLM 108 to output a rating for the one or more actions generated by the first LLM 106. As discussed above, the rating may include a score for the one or more actions, and/or feedback regarding the one or more actions in natural language form. This rating indicates whether the one or more activities are realistic and are consistent with the persona defined by the persona data 110 and/or the historical data stored in the agent memory 104.

Next, in step 306, the control module 102 causes the first LLM 106 to update the one or more actions based on the rating output by the second LLM 108. This ensures that the one or more activities are realistic for the persona defined by the persona data 110 and are consistent with the internal state of the agent 100 characterized by the historical data stored in the agent memory 104.

Next, in step 308, the control module 102 causes the one or more actions to be performed in the simulated environment 200. As discussed above, performance of the daily activities may be realized by the one or more low-level controllers 112.

Next, in step 310, the control module 102 causes the first LLM 106 to update the one or more action based on one or more observations of the simulated environment 200. As discussed above, these observations may be made by the one or more low-level controllers 112 which control the interaction between the agent 100 and the simulated environment 200. In this manner, the experiences of the agent 100 in the simulated environment 200 can be utilized to refine the one or more actions generated by the first LLM 106.

In the embodiments described above, the one or more actions generated by the agent 100 constitute a daily plan representing various activities to be performed in the simulated environment 200. However, it will be appreciated that the one or more actions are not limited to this context, and the information processing system 10 may be used to generate activities for use in different contexts. For example, the information processing system 10 may be configured to generate one or more actions that the agent 100 is to take in relation to an automated recommendation system to assess the quality of the recommendations produced by the recommendation system.

While embodiments of the present disclosure have been described with reference to the drawings and examples, it should be noted that various modifications and revisions may be implemented by those skilled in the art based on this description. Accordingly, such modifications and revisions are included within the scope of the present disclosure.

1. An information processing system comprising:
a processor system; and
a memory system;
wherein the memory system stores instructions which, when executed by the processor system, cause the information processing system to instantiate an agent comprising:
an agent memory for storing historical data associated with the agent;
a first large language model conditioned on persona data characterizing a persona of the agent;
a second large language model; and
a control module configured to:
cause the first large language model to generate one or more actions based on the historical data,
cause the second large language model to output a rating for the one or more actions generated by the first large language model, and
cause the first large language model to update the one or more actions based on the rating output by the second large language model.

2. The information processing system according to claim 1, wherein the control module is configured to:
cause the one or more actions to be performed in a simulated environment, and
cause the first large language model to update the historical data based on one or more observations taken from the simulated environment.

3. The information processing system according to claim 1, wherein:
the agent comprises a descriptor module configured to convert the one or more observations taken from the simulated environment into a natural language description of the one or more observations, and
the control module is configured to cause the first large language model to update the one or more actions based on the natural language description of the one or more observations.

4. The information processing system according to claim 2, wherein the agent comprises:
one or more low-level controllers configured to perform the one or more actions in the simulated environment.

5. A non-transitory computer-readable medium storing instructions which, when executed by an information processing system, cause the information processing system to instantiate an agent comprising:
an agent memory for storing historical data associated with the agent;
a first large language model conditioned on persona data characterizing a persona of the agent;
a second large language model; and
a control module configured to:
cause the first large language model to generate one or more actions based on the historical data,
cause the second large language model to output a rating for the one or more actions generated by the first large language model, and
cause the first large language model to update the one or more actions based on the rating output by the second large language model.
